(19) United States
(12) Patent Application Publication
(10) Pub. No.: US 2017/0010544 A1
(43) Pub. Date: Jan. 12, 2017

(54) COIL ASSEMBLY, ELECTROMAGNETIC ACTUATOR, STAGE POSITIONING DEVICE, LITHOGRAPHIC APPARATUS AND DEVICE MANUFACTURING METHOD

(71) Applicants: ASML NETHERLANDS B.V., Veldhoven (NL); ASML HOLDING NV, Veldhoven (NL)

(72) Inventors: Yang-Shan HUANG, Veldhoven (NL); Minkyu KIM, Wilton, CT (US); Gerard Johannes Pieter NIJSSE, Best (NL)

(73) Assignees: ASML NETHERLANDS B.V., Veldhoven (NL); ASML HOLDING N.V., Veldhoven (NL)

(21) Appl. No.: 15/113,428

(22) PCT Filed: Dec. 19, 2014
(86) PCT No.: PCT/EP2014/078677

§ 371 Date: Jul. 21, 2016

Related U.S. Application Data
(60) Provisional application No. 61/930,343, filed on Jan. 22, 2014.

(51) Int. Cl. G03F 7/20; H02K 9/00; H02K 3/48; H01F 7/10

(52) U.S. Cl. CPC G03F 7/70725; H01F 7/10; H02K 9/005; H02K 3/48

(57) ABSTRACT

A coil assembly for an electromagnetic actuator or motor, includes a magnetic core including at least one pair of slots; a coil, at least partly mounted inside the at least one pair of slots; and a cooling member, the cooling member being mounted to a surface of the coil.

### CROSS-REFERENCE TO RELATED APPLICATIONS

This application claims the benefit of U.S. provisional application 61/930,343, which was filed on Jan. 22, 2014 and which is incorporated herein in its entirety by reference.

### FIELD

The present invention relates to a coil assembly for an electromagnetic actuator, an electromagnetic actuator, a stage positioning device, a lithographic apparatus and a method for manufacturing a device.

### BACKGROUND

A lithographic apparatus is a machine that applies a desired pattern onto a substrate, usually onto a target portion of the substrate. A lithographic apparatus can be used, for example, in the manufacture of integrated circuits (ICs). In such a case, a patterning device, which is alternatively referred to as a mask or a reticle, may be used to generate a circuit pattern to be formed on an individual layer of the IC. This pattern can be transferred onto a target portion (e.g.

including part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Conventional lithographic apparatus include so-called steppers, in which each target portion is irradiated by exposing an entire pattern onto the target portion at once, and so-called scanners, in which each target portion is irradiated by scanning the pattern through a radiation beam in a given direction (the “scanning”-direction) while synchronously scanning the substrate parallel or anti-parallel to this direction. In view of an ever increasing demand for integrated circuits, there is an ever increasing demand in an increased performance of lithographical apparatuses. In particular, there is an ever increasing desire to increase the throughput of such apparatuses. Such an increased throughput can e.g. be realized by increasing the number of substrates processed per unit of time or by increasing the size of the substrates, i.e. processing larger substrates would result in more ICs manufactured per unit of time.

Both options increase the burden put on the positioning devices applied during the scanning-exposure process. As such, it is desirable to improve the performance of positioning devices as applied in a lithographical apparatus. At present, the performance of such positioning devices, typically electromagnetic actuators or motors, is limited due to a less than optimal cooling of such devices.

### SUMMARY

It is desirable to provide in a positioning device having an improved cooling arrangement.

According to an aspect of the invention, there is provided a coil assembly for an electromagnetic actuator or motor, the coil assembly comprising:
a magnetic core comprising at least one pair of slots;
a coil, at least partly mounted inside said at least one pair of slots;
   wherein the coil assembly further comprises a cooling member, said cooling member being mounted to a surface of said coil.

According to another aspect of the invention, there is provided an electromagnetic actuator comprising a first member and a second member, wherein the first member comprising a coil assembly according to the invention and wherein the second member is configured to, in use, co-operate with the first member to generate a force between the first member and the second member upon energizing of the one or more coils.

According to yet another aspect of the present invention, there is provided a lithographic apparatus comprising:
an illumination system configured to condition a radiation beam;
a support constructed to support a patterning device, the patterning device being capable of imparting the radiation beam with a pattern in its cross-section to form a patterned radiation beam;
a substrate table constructed to hold a substrate; and
a projection system configured to project the patterned radiation beam onto a target portion of the substrate,
   wherein the apparatus further comprises an electromagnetic actuator according to the present invention or an electromagnetic motor according to the invention for positioning either the support or the substrate table.

According to yet another aspect of the invention, there is provided a device manufacturing method comprising transferring a pattern from a patterning device onto a substrate, comprising a step of positioning the patterning device relative to the substrate using an electromagnetic actuator or electromagnetic motor according to an embodiment of the present invention.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2 depicts a coil assembly of an electromagnetic actuator as known in the art;

FIG. 3 depicts a coil assembly according to a first embodiment of the present invention;

FIG. 4 depicts a coil assembly according to a second embodiment of the present invention;

FIG. 5 depicts part of a coil assembly according to an embodiment of the present invention;

FIG. 6 depicts a coil assembly according to a third embodiment of the present invention;

FIG. 7 depicts an actuator according to an embodiment of the present invention;

FIG. 8 depicts a linear motor according to an embodiment of the present invention;

### DETAILED DESCRIPTION

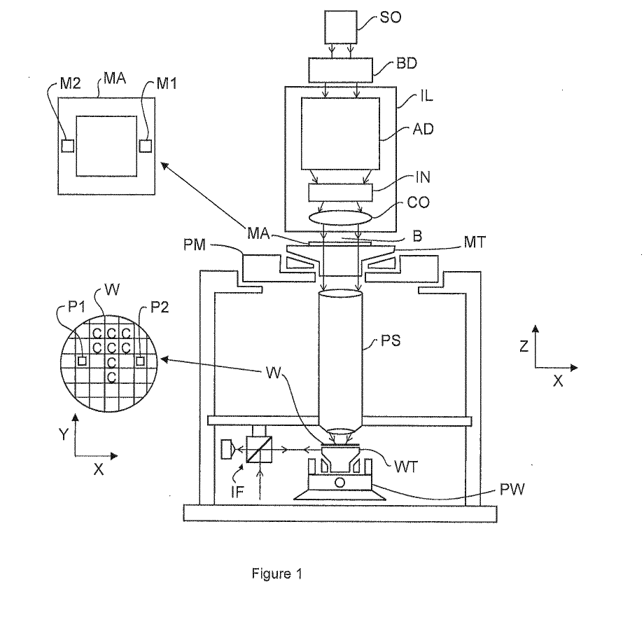

FIG. 1 schematically depicts a lithographic apparatus according to an embodiment of the invention. The apparatus includes an illumination system (illuminator) IL configured to condition a radiation beam B (e.g. UV radiation or any other suitable radiation), a support structure or patterning device support (e.g. a mask table) MT constructed to support a patterning device (e.g. a mask) MA and connected to a first positioning device PM configured to accurately position the patterning device in accordance with certain parameters. The apparatus also includes a substrate table (e.g. a wafer table) WT or “substrate support” constructed to hold a substrate (e.g. a resist-coated wafer) W and connected to a second positioning device PW configured to accurately position the substrate in accordance with certain parameters. The apparatus further includes a projection system (e.g. a refractive projection lens system) PS configured to project a pattern imparted to the radiation beam B by patterning device MA onto a target portion C (e.g. including one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure supports, i.e. bears the weight of, the patterning device. It holds the patterning device in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as needed. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section so as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable minor array employs a matrix arrangement of small minors, each of which can be individually tilted so as to reflect an incoming radiation beam in different directions. The tilted minors impart a pattern in a radiation beam which is reflected by the minor matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g. employing a transmissive mask). Alternatively, the apparatus may be of a reflective type (e.g. employing a programmable mirror array of a type as referred to above, or employing a reflective mask).

The lithographic apparatus may be of a type having two (dual stage) or more substrate tables or “substrate supports” (and/or two or more mask tables or “mask supports”). In such “multiple stage” machines the additional tables or supports may be used in parallel, or preparatory steps may be carried out on one or more tables or supports while one or more other tables or supports are being used for exposure.

The lithographic apparatus may also be of a type wherein at least a portion of the substrate may be covered by a liquid having a relatively high refractive index, e.g. water, so as to fill a space between the projection system and the substrate. An immersion liquid may also be applied to other spaces in the lithographic apparatus, for example, between the patterning device (e.g. mask) and the projection system. Immersion techniques can be used to increase the numerical aperture of projection systems. The term “immersion” as used herein does not mean that a structure, such as a substrate, must be submerged in liquid, but rather only means that a liquid is located between the projection system and the substrate during exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may include an adjuster AD configured to adjust the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may include various other components, such as an integrator IN and a condenser CO. The illuminator may be used to condition the radiation beam, to have a desired uniformity and intensity distribution in its cross-section.

The radiation beam B is incident on the patterning device (e.g., mask) MA, which is held on the support structure (e.g., mask table) MT, and is patterned by the patterning device. Having traversed the patterning device (e.g. mask) MA, the radiation beam B passes through the projection system PS, which focuses the beam onto a target portion C of the substrate W. With the aid of the second positioning device PW and position sensor IF (e.g. an interferometric device, linear encoder or capacitive sensor), the substrate table WT can be moved accurately, e.g. so as to position different target portions C in the path of the radiation beam B. Similarly, the first positioning device PM and another position sensor (which is not explicitly depicted in FIG. 1) can be used to accurately position the patterning device (e.g. mask) MA with respect to the path of the radiation beam B, e.g. after mechanical retrieval from a mask library, or during a scan. In general, movement of the support structure (e.g. mask table) MT may be realized with the aid of a long-stroke module (coarse positioning) and a short-stroke module (fine positioning), which form part of the first positioning device PM. Similarly, movement of the substrate table WT or “substrate support” may be realized using a long-stroke module and a short-stroke module, which form part of the second positioner PW. In accordance with the present invention, the first and/or second positioner can e.g. comprise one or more actuators or motors according to an embodiment of the present invention to displace the respective substrate or patterning device. By the application of an actuator or motor according to the present invention, an improved performance of the apparatus can be obtained; in particular, the actuators or motors according to the present invention enable an increased acceleration (and deceleration) of the substrate table WT and the support structure (e.g. mask table) MT, thereby enabling a larger throughput of the lithographic apparatus.

It is further worth nothing that an actuator or motor according to an embodiment of the present invention may also be applied for positioning of other components or elements in the lithographic apparatus, e.g. optical elements, masking blades, etc. In the case of a stepper (as opposed to a scanner) the support structure (e.g. mask table) MT may be connected to a short-stroke actuator only, or may be fixed. Patterning device (e.g. mask) MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g. mask) MA, the patterning device alignment marks may be located between the dies.

The depicted apparatus could be used in at least one of the following modes:
1. In step mode, the support structure (e.g. mask table) MT or “mask support” and the substrate table WT or “substrate support” are kept essentially stationary, while an entire pattern imparted to the radiation beam is projected onto a target portion C at one time (i.e. a single static exposure). The substrate table WT or “substrate support” is then shifted in the X and/or Y direction so that a different target portion C can be exposed. In step mode, the maximum size of the exposure field limits the size of the target portion C imaged in a single static exposure.
2. In scan mode, the support structure (e.g. mask table) MT or “mask support” and the substrate table WT or “substrate support” are scanned synchronously while a pattern imparted to the radiation beam is projected onto a target portion C (i.e. a single dynamic exposure). The velocity and direction of the substrate table WT or “substrate support” relative to the support structure (e.g. mask table) MT or “mask support” may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.
3. In another mode, the support structure (e.g. mask table) MT or “mask support” is kept essentially stationary holding a programmable patterning device, and the substrate table WT or “substrate support” is moved or scanned while a pattern imparted to the radiation beam is projected onto a target portion C. In this mode, generally a pulsed radiation source is employed and the programmable patterning device is updated as needed after each movement of the substrate table WT or “substrate support” or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

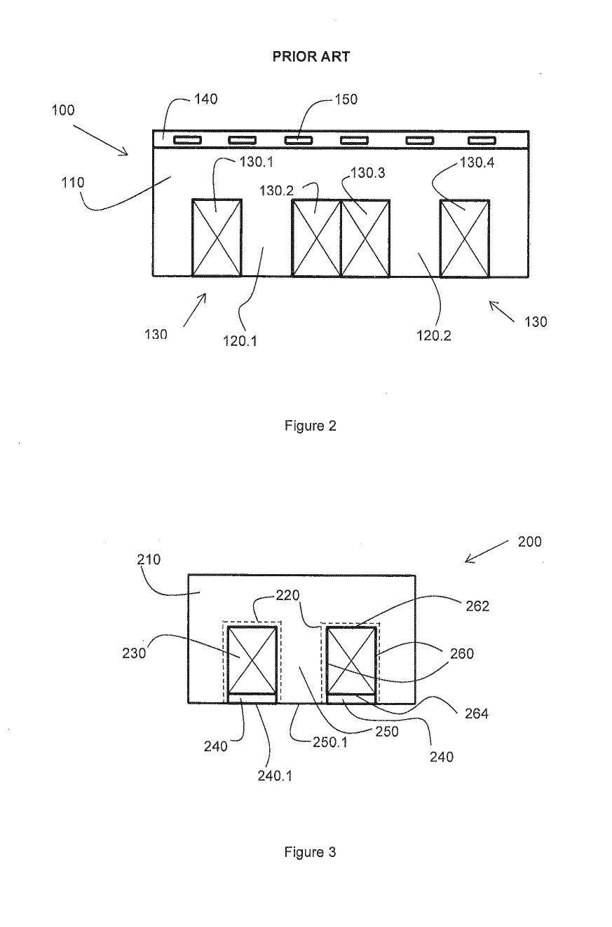

FIG. 2 schematically depicts a cross-sectional view of a coil arrangement of an electromagnetic actuator as known in the art. The coil arrangement 100 comprises a magnetic yoke 110 provided with a number of slots configured to receive one or more coils 130. In the arrangement as shown, two coils 130 are provided, coil 1 (having coil sides 130.1 and 130.2) being wound about a tooth 120.1, coil 2 (having coil sides 130.3 and 130.4) being wound about a tooth 120.2. Typically, the coils comprise a plurality of turns of a wire- or band-shaped conductor, e.g. made from Cu or Al.

In accordance with an embodiment of the present invention, the term ‘magnetic yoke’ is used to denote a structure made from a material having a high relative permeability (e.g. >100) such as ferromagnetic materials such as steel or rare-earth alloys such as CoFe, SiFe or the like. Typically, a magnetic yoke is a laminated core made by assembling a plurality of ferromagnetic sheets, in order to reduce so-called iron core losses.

The coil arrangement as shown further comprises a cooling member 140 which is mounted to an outer surface of the magnetic yoke 110 and e.g. provided with cooling channels 150 through which a cooling fluid can flow.

In the known arrangement, the cooling of the coils 130 has been found to be far from optimal, resulting in either a poor performance of the motor (in case the current through the coils is kept comparatively low) or a comparatively high operating temperature of the coils, thus posing a risk to a degradation of isolation of the coils.

In accordance with an embodiment of the present invention, an alternative way of cooling a coil assembly of an electromagnetic motor is proposed. FIG. 3 schematically shows a cross-sectional view of a first embodiment of a coil arrangement according to the present invention. The coil arrangement 200 as shown comprises a magnetic yoke 210 comprising at least one pair of slots to receive a coil.

In the embodiment as shown, the magnetic yoke 210 has two slots, indicated by the dotted line 220. A coil 230 is mounted in said pair of slots 220. Compared to the arrangement of FIG. 2, the coil 230 does not fill the slot entirely, but the cross-section of the coil is selected smaller than the cross-section of the slot, in order accommodate a cooling member 240. In accordance with an embodiment of the present invention, a cooling member 240 is mounted to a surface of said coil 230. In the embodiment as shown, the cooling member 240 is mounted to an outer surface of the coil 230 which is non-contacting the slot 220 or not facing a surface of the slot 220. In an embodiment, the cross-sectional size of the coil 230 and the cooling member 240 can be selected such that both can fit inside the cross-section of the slot 220. In an embodiment, the cooling member 240 has a surface 240.1 which is flush or aligned with an end-surface 250.1 of a tooth 250 enclosed by the slots 220.

In the arrangement as shown, both coil sides that are mounted in the pair of slots 220 are provided with a cooling member 240.

Within the meaning of the present invention, the surfaces 260 of the coil 230, i.e. the surfaces facing a side surface of the slots 220, are referred to as side surfaces of the coil, whereas the surface 262 of the coil facing the bottom of the slot is referred to as the bottom surface of the coil and the surface 264 of the coil near the top of the slot is referred to as the top surface of the coil.

The cooling member as applied in an embodiment of the present invention, i.e. mounted to a surface of a coil which is at least partly mounted in a magnetic yoke, provides in a more effective and direct cooling of the coil. Compared to the known arrangement as shown in FIG. 2, the coil or coils of the coil assembly as shown in FIG. 3 are directly cooled by a cooling member 240 that is mounted to a surface of the coil 230, whereas in the arrangement of FIG. 2, the heat generated by the coils needs to be transferred, via the magnetic yoke 110, to the cooling member 140. As a result, the temperature of the coils 230 can be kept lower, even when an increased current density is applied. In this respect, it should be noted that it can be considered counterintuitive to apply a cooling member 240 directly on a coil surface of a coil assembly when the coils are embedded in slots of a magnetic yoke. Typically, a trade-off needs to be made to divide the available cross-section between a coil cross-section and a magnetic yoke or core cross-section. When, in addition, a cooling member needs to be accommodated in the available cross-section, this will either result in a decreased cross-section available for the coil (resulting, for a given nominal current, in an increased current density and thus in increased Ohmic losses), or in a decreased cross-section available for the magnetic yoke (resulting in an increased saturation level, thus requiring an increased current to obtain the same flux density and force), or both. Surprisingly however, it has been found that these drawbacks are more than compensated by the increased effectiveness of the cooling. The improved cooling as obtained by an embodiment of the present invention enables the selection of a smaller coil cross-section and/or a larger tooth area, while keeping the overall motor or actuator volume substantially the same. Therefore, more magnetic flux may be generated within the same motor volume resulting in an improved motor or actuator performance. Alternatively, the same motor or actuator performance could be realized in a smaller volume when an improved cooling is available. Using the more direct cooling as proposed by an embodiment of the present invention, enables the coil or coils of the coil assembly to be cooled more effectively, enabling to improve the performance of an actuator or motor in which the coil assembly is applied.

In accordance with an embodiment of the present invention, various options exist for the application of the cooling member 240 as shown.

In the embodiment as shown in FIG. 3, the cooling member 240 is mounted near the top of the tooth 250. In an embodiment, a coil assembly 200 as shown is used in combination with a magnet assembly comprising one or more permanent magnets. In such arrangement, the permanent magnets of the magnet assembly (not shown in FIG. 3) face the coil or coils 230 of the coil assembly. By arranging the cooling member 240 in the position as shown, the cooling member 240 is arranged in between the coil or coils 230 and the permanent magnets. In such arrangement, the cooling member 240 thus shields the permanent magnets from the comparatively hot coil or coils 230. By doing so, a heat transfer of the coil or coils 230 towards the permanent magnets of the magnet assembly can be avoided or mitigated. As a result, the cooling member 240 not only provides in an effective cooling of the coil 230 but also enables to maintain the permanent magnets at a reduced temperature. As known by the skilled person, maintaining a permanent magnet at a reduced temperature may result in an elevated flux density and may avoid a (permanent) demagnetization of the permanent magnet. However, when a cooling member 240 is applied in the position as shown, i.e. whereby the cooling member 240 may face a permanent magnet, care should be taken that the cooling member 240 does not causes an excessive additional damping or causes too much additional losses, in particular Eddy current losses induced in the cooling member 240. Note that such damping or losses may be avoided or mitigated by a proper selection of the material of the cooling member, e.g. selection of a material having a low electrical conductivity, or by introducing slits in the cooling member 240, thereby reducing the generated Eddy currents and thus the Eddy current losses.

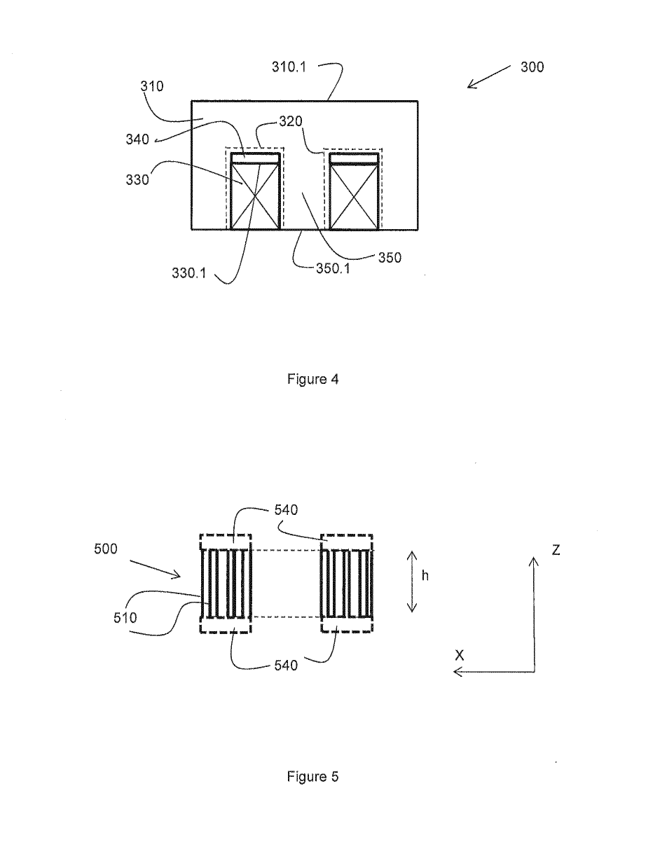

FIG. 4 schematically shows a cross-sectional view of a second embodiment of a coil arrangement according to the present invention. The coil arrangement 300 as shown comprises a magnetic yoke 310 comprising at least one pair of slots 320 to receive a coil 330.

In the embodiment as shown, the magnetic yoke 310 has two slots, indicated by the dotted line 320. A coil 330 is mounted in said pair of slots 320. Compared to the arrangement of FIG. 2, the coil 330 does not fill the slot entirely, but the cross-section of the coil is selected smaller than the cross-section of the slot, in order accommodate a cooling member 340. In the embodiment as shown, the cooling member 340 is mounted to a coil surface 330.1 which faces a bottom of the slots 320. With respect to the reduced available cross-sectional space for either the coil 330 or the magnetic yoke 310, the same considerations apply as discussed in relationship with FIG. 3. In a similar manner, the arrangement of the cooling member 340 as shown in FIG. 4 enables a more effective cooling of the coil 330 that is embedded in the slots 320. Compared to the embodiment of FIG. 3, it is worth noting that the arrangement of FIG. 4 also provides in an effective cooling of the magnetic yoke 310. As such, an outer surface 310.1 of the magnetic yoke 310 may be kept at a lower temperature, thus avoiding or mitigating the heating of components that are near the coil assembly, e.g. the substrate table, the mask table or the support structure as discussed above. Compared to the embodiment of FIG. 3, it can be noted that the issue of an increased damping or increased (Eddy current) losses is much smaller in the embodiment of FIG. 4.

In an embodiment of the present invention, a coil assembly is provided which comprises both the cooling member 240 as shown in FIG. 3 and the cooling member 340 as shown in FIG. 4.

The positioning of the cooling member as shown in FIGS. 3 and 4 is particularly favorable in case so-called band-coils are used, i.e. coils comprising a band-shaped conductor to conduct an electrical current. FIG. 5 schematically shows a cross-section of such a coil 500 comprising of a plurality of windings 510 of a band-shaped conductor having a height h. In between adjacent windings or turns, an electrical insulator is provided (not shown). As a result, such a band-coil has a comparatively low thermal conductivity in the X-direction (as an electrical insulator in most cases has a poor thermal conductivity as well) and a high thermal conductivity in the Z-direction. As such, it is favorable to mount one or more cooling members 540 on the coil surfaces that are perpendicular to the Z-direction.

In an embodiment, the coil assembly according to the present invention comprises multiple coil sides per slot, i.e. each slot accommodating coil sides of different coils. In such an arrangement, a cooling member can be positioned in between the coil sides of the different coils.

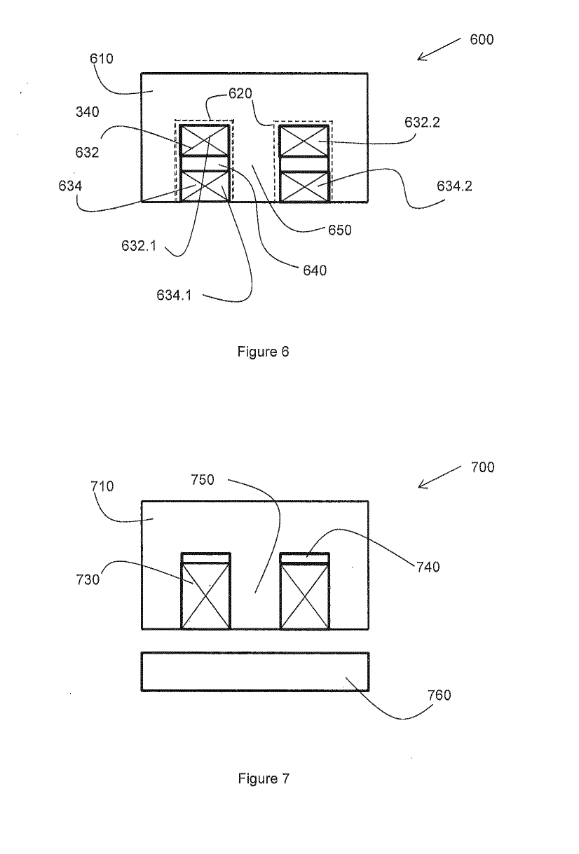

FIG. 6 schematically shows such an arrangement. FIG. 6 schematically shows a cross-sectional view of a third embodiment of a coil arrangement according to the present invention. The coil arrangement 600 as shown comprises a magnetic yoke 610 comprising a pair of slots, indicated by the dotted line 620. In said pair of slots 620, two coils 632 and 634 are mounted; the slot on the left thus occupying a coil side 632.1 of coil 632 and a coil side 634.1 of coil 634, the slot on the right thus occupying a coil side 632.2 of coil 632 and a coil side 634.2 of coil 634. The coil sides do not fill the slot entirely, rather, a cooling member 640 is mounted in between the coils 632 and 634, in particular between the coil sides 632.1 and 634.1 and between coil sides 632.2 and 634.2 by subdividing the coil occupying a pair of slots into multiple coils, a similar improved cooling effect can be realized.

Note that the same principle can be applied when more than two coil sides are occupying one slot as well. As such, the cooling member as shown in FIG. 6 may e.g. be applied in so-called multilayer windings as e.g. applied in multiphase induction motors or multiphase permanent magnet motors.

In general, the coil assembly according to the present invention can be applied in electromagnetic actuators, such as actuators used in the aforementioned short stroke module of the positioning device PM or PW, and in electromagnetic motors such as linear or planar motors as can be used in long stroke modules of the positioning device PM or PW.

In general, an electromagnetic actuator or motor comprises a coil assembly as a first member, cooperating with a second member, thereby generating a force between the first member and the second member.

In so-called reluctance type motors or actuators, the second member comprises a magnetic member such as a magnetic yoke, e.g. made from a ferromagnetic material having a relative permeability μᵣ>100. In such reluctance type actuators or motors, an attractive force is generated between the first member and the second member when a current is provided to the coil or coils of the coil assembly.

In so-called permanent magnet motors or actuators, the second member comprises one or more permanent magnets, optionally mounted to a magnetic member such as a magnetic yoke.

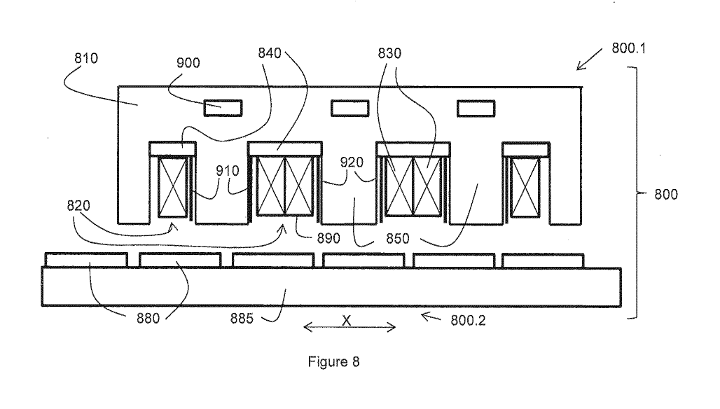

The followings FIGS. 7-8 schematically show some examples of electromagnetic motors/actuators which may beneficially be equipped with a coil assembly according to the present invention.

FIG. 7 schematically shows a cross-sectional view of an electromagnetic reluctance-type actuator 700 comprising a first member that comprises a magnetic yoke 710 provide with a pair of slots that are occupied by a coil 730 and a cooling member 740. The slots are separated by a tooth 750. The actuator 700 further comprises a second member 760, the second member 760 comprising a magnetic yoke such as a ferromagnetic yoke and is configured to co-operate with the first member. When a current is supplied to the coil 730 of the coil assembly of the first member, an attractive force is generated between the first member and the second member.

Such an actuator may e.g. be applied for accurate, short stroke, positioning of an object table such as a substrate table or a pattering device support. In such arrangement, a plurality of such actuators may e.g. be applied to position the object table in multiple degrees of freedom, e.g. 6 DOF (degrees of freedom). In such arrangement, the second members of the actuators (e.g. second member 760 of FIG. 7) may than be mounted to a support supporting the object to be positioned. In such arrangement, whereby multiple actuators are used, the second member may be common to more than one actuator. Phrased differently, in order to position an object in multiple degrees of freedom, a second member such as magnetic yoke 760 may be surrounded by a plurality of coil assemblies according to an embodiment of the invention, thereby enabling the generation of forces on the second member in different degrees of freedom.

FIG. 8 schematically shows an electromagnetic motor 800, also referred to as a linear motor comprising a first member 800.1 comprising a coil assembly according to the present invention, and a second member 800.2 comprising an array of alternatingly polarized permanent magnets 880 mounted to a magnetic yoke 885. In the embodiment as shown, the coil assembly comprises a magnetic yoke 810 provide with four slots 820 which are occupied by three coils 830. Note that the outer slots are occupied by a coil side of the outer coils of the three coils, whereas the two most inner slots are provided with two coil sides. In accordance with an embodiment of the present invention, the coil assembly further comprises cooling members 840 that are mounted to a surface of the coils. In the arrangement as shown, the cooling members 840 are mounted to a surface of the coils facing a bottom of the slots 820. The slots are further separated by teeth 850. In order to further improve the cooling of the coils 830, additional cooling members (not shown) could also be applied to the surface of the coils 890 that faces the permanent magnet array 880. Optionally, the magnetic yoke 810 of the coil assembly may also be provided with a cooling member 900. In the embodiment as shown, the cooling member 900 comprises a plurality of rectangular shaped cooling channels which can be configured to receive a cooling fluid such as a cooling gas of a cooling liquid such as water. In the embodiment as shown, a thermal insulation layer 910 is provided on a surface of the coils facing a side surface 920 of the slots. Such optional thermal insulation layer may be useful in that it hinders heat from the coils to migrate to the teeth 850 and forces the heat to migrate towards the cooling member 840. By doing so, excessive heating of the teeth 850 can be avoided or mitigated.

As an alternative to the application of the thermal insulation layer 910, a cooling member, similar to the cooling members 840, may also be applied to the coil surfaces facing the side surfaces 920 of the slots.

It is worth noting that the application of the thermal insulation layer 910, the application of an additional cooling member 900 in the magnetic yoke 810 or the application of a cooling member to a coil surface facing a side surface of the slots may be applied in all of the above described embodiments of the coil assembly according to the invention.

The electromagnetic motor as schematically shown in FIG. 8 may e.g. be applied as part of the long-stroke module in a lithographic apparatus to position and displace objects such as patterning devices or substrates over comparatively large distances, e.g. >500 mm. By appropriately energizing the coils 830, e.g. using a three-phase alternating current supply, a displacement of the first member 800.1 relative to the second member 800.2 in the X-direction can be realized.

The cooling member as applied in the coil assembly according to the present invention, i.e. cooling members 240, 340, 540, 640, 740 or 840 as described above, can be implemented in various ways.

As an example, the cooling member can comprise one or more cooling channels that are provided in an enclosure, e.g. a stainless steel or ceramic enclosure. As mentioned above, in case the cooling member is facing a permanent magnet and is configured to displace relative to the permanent magnet, care should be taken to avoid excessive damping or losses. The one or more cooling channels may e.g. be configured to receive a cooling fluid such as a gas or a liquid.

As an alternative, the cooling member could also comprise a heat pipe or the like to remove the heat generated in the coil or coils.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device MA defines the pattern created on a substrate W. The topography of the patterning device MA may be pressed into a layer of resist supplied to the substrate whereupon the resist is cured by applying electromagnetic radiation, heat, pressure or a combination thereof. The patterning device MA is moved out of the resist leaving a pattern in it after the resist is cured.

The terms “radiation” and “beam” used herein encompass all types of electromagnetic radiation, including ultraviolet (UV) radiation (e.g. having a wavelength of or about 365, 248, 193, 157 or 126 nm) and extreme ultra-violet (EUV) radiation (e.g. having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

The descriptions above are intended to be illustrative, not limiting. Thus, it will be apparent to one skilled in the art that modifications may be made to the invention as described without departing from the scope of the claims set out below.

1. A coil assembly for an electromagnetic actuator or motor, the coil assembly comprising:
a magnetic core comprising at least one pair of slots;
a coil, at least partly mounted inside said at least one pair of slots; and
a cooling member, said cooling member being mounted to a surface of said coil.

2. The coil assembly according to claim 1, wherein the surface of said coil is inside said at least one pair of slots.

3. The coil assembly according to claim 1, wherein the cooling member is mounted to a side surface of said at least one pair of slots.

4. The coil assembly according to claim 1, wherein the cooling member is mounted to a bottom surface or a top surface of said at least one pair of slots.

5. The coil assembly according to claim 1, wherein the surface of the coil to which the cooling member is mounted is a surface non-contacting the at least one pair of slots.

6. The coil assembly according to claim 5, wherein an outer surface of the cooling member is flush or aligned with an end-surface of a tooth enclosed by the at least one pair of slots.

7. The coil assembly according to claim 1, wherein the cooling member comprises a cooling channel configured to receive a cooling fluid.

8. The coil assembly according to claim 1, further comprising a thermally insulating layer mounted to a side surface of said at least one pair of slots.

9. The coil assembly according to claim 1, wherein a further cooling member is provided to the magnetic yoke.

10. An electromagnetic actuator comprising a first member and a second member, wherein the first member comprises a coil assembly according to claim 1 and wherein the second member is configured to, in use, co-operate with the first member to generate a force between the first member and the second member upon energizing of the coil.

11. The electromagnetic actuator according to claim 10, wherein the second member comprises a magnetic yoke or a permanent magnet assembly.

12. An electromagnetic motor comprising a coil assembly according to claim 1 and a permanent magnet assembly comprising an array of alternatingly polarized permanent magnets mounted to a magnetic yoke, the coil of the coil assembly comprising a multi-phase winding.

13. A stage positioning device for positioning an object, the stage positioning device comprising:
one or more electromagnetic actuators according to claim 10 for providing a short stroke positioning of the object, and
one or more electromagnetic motors for providing a long stroke positioning of the object.

14. A lithographic apparatus comprising:
an illumination system configured to condition a radiation beam;
a support constructed to support a patterning device, the patterning device being capable of imparting the radiation beam with a pattern in its cross-section to form a patterned radiation beam;
a substrate table constructed to hold a substrate;
a projection system configured to project the patterned radiation beam onto a target portion of the substrate, and
a stage positioning device according to claim 13.

15. A lithographic apparatus comprising:
an illumination system configured to condition a radiation beam;
a support constructed to support a patterning device, the patterning device being capable of imparting the radiation beam with a pattern in its cross-section to form a patterned radiation beam;
a substrate table constructed to hold a substrate;
a projection system configured to project the patterned radiation beam onto a target portion of the substrate, and
an electromagnetic actuator according to claim 10 for positioning either the support or the substrate table.

16. A device manufacturing method comprising transferring a pattern from a patterning device onto a substrate, and positioning the patterning device relative to the substrate using an electromagnetic actuator according to claim 10.

17. The stage positioning device according to claim 13, wherein the object is a patterning device or a substrate.

18. A lithographic apparatus comprising:
an illumination system configured to condition a radiation beam;
a support constructed to support a patterning device, the patterning device being capable of imparting the radiation beam with a pattern in its cross-section to form a patterned radiation beam;
a substrate table constructed to hold a substrate;
a projection system configured to project the patterned radiation beam onto a target portion of the substrate, and
an electromagnetic motor according to claim 12 for positioning either the support or the substrate table.

19. A device manufacturing method comprising transferring a pattern from a patterning device onto a substrate, and positioning the patterning device relative to the substrate using an electromagnetic motor according to claim 12.
